(19) United States
(12) Patent Application Publication
(10) Pub. No.: US 2024/0282678 A1
(43) Pub. Date: Aug. 22, 2024

(54) SEMICONDUCTOR DEVICE

(71) Applicant: Rohm Co., Ltd., Kyoto-shi (JP)

(72) Inventors: Ryotaro KAKIZAKI, Kyoto-shi (JP); Yasumasa KASUYA, Kyoto-shi (JP)

(21) Appl. No.: 18/651,064

(22) Filed: Apr. 30, 2024

Related U.S. Application Data
(63) Continuation of application No. PCT/JP2022/043282, filed on Nov. 24, 2022.

(30) Foreign Application Priority Data
Dec. 1, 2021 (JP) 2021-195179

(51) Int. Cl. H01L 23/495; H01L 23/00; H01L 23/29; H01L 23/31

(52) U.S. Cl. CPC H01L 23/49541; H01L 23/293; H01L 23/3142; H01L 23/49513; H01L 24/40; H01L 24/48; H01L 24/73; H01L 24/37; H01L 24/45; H01L 2224/37124; H01L 2224/40247; H01L 2224/45144; H01L 2224/48247; H01L 2224/73271; H01L 2924/13055; H01L 2924/13091

(57) ABSTRACT

A semiconductor device includes: a semiconductor element; a first lead including a die pad portion and a first terminal portion; and a sealing resin. A first lead reverse surface is exposed from a second resin surface and spaced apart from a third resin surface in a first direction. The first terminal portion includes a first portion and a second portion. Only one set of the first portion passes through the third resin surface. The first portion is spaced apart from the second resin surface in a z direction. The second portion is located on a first side in the z direction relative to the first portion and used for mounting.

### TECHNICAL FIELD

The present disclosure relates to a semiconductor device.

### BACKGROUND ART

JP-A-2017-174951 discloses an example of a semiconductor device that includes a first lead including a first pad having a pad obverse surface and a pad reverse surface, a second lead, a third lead, a semiconductor element mounted on the pad obverse surface, and a sealing resin in contact with the pad obverse surface and covering the semiconductor element. The first lead, the second lead, and the third lead have a first terminal, a second terminal, and a third terminal, respectively, that extend in the same direction. The first terminal, the second terminal, and the third terminal are inserted into through-holes of a circuit board or the like, whereby the semiconductor device is mounted on the circuit board. In the case where the semiconductor device is attached to a heat sink, an insulating sheet may be provided between the pad reverse surface and the heat sink.

### BRIEF DESCRIPTION OF THE DRAWINGS

FIG. 1 is a perspective view showing a semiconductor device according to a first embodiment of the present disclosure.

FIG. 2 is a perspective view showing the semiconductor device according to the first embodiment of the present disclosure.

FIG. 3 is a perspective view showing the semiconductor device according to the first embodiment of the present disclosure.

FIG. 4 is a perspective view showing main parts of the semiconductor device according to the first embodiment of the present disclosure.

FIG. 5 is a perspective view showing main parts of the semiconductor device according to the first embodiment of the present disclosure.

FIG. 6 is a plan view showing the semiconductor device according to the first embodiment of the present disclosure.

FIG. 7 is a bottom view showing the semiconductor device according to the first embodiment of the present disclosure.

FIG. 8 is a front view showing the semiconductor device according to the first embodiment of the present disclosure.

FIG. 9 is a side view showing the semiconductor device according to the first embodiment of the present disclosure.

FIG. 10 is a plan view showing main parts of the semiconductor device according to the first embodiment of the present disclosure.

FIG. 11 is a bottom view showing main parts of the semiconductor device according to the first embodiment of the present disclosure.

FIG. 12 is a cross-sectional view along line XII-XII in FIG. 11.

FIG. 13 is a cross-sectional view along line XIII-XIII in FIG. 11.

FIG. 14 is a cross-sectional view along line XIV-XIV in FIG. 11.

FIG. 15 is a cross-sectional view along line XV-XV in FIG. 11.

FIG. 16 is a cross-sectional view showing a use state of the semiconductor device according to the first embodiment of the present disclosure.

FIG. 17 is a cross-sectional view showing a first variation of the semiconductor device according to the first embodiment of the present disclosure.

FIG. 18 is a cross-sectional view showing a use state of the first variation of the semiconductor device according to the first embodiment of the present disclosure.

FIG. 19 is a perspective view showing a second variation of the semiconductor device according to the first embodiment of the present disclosure.

FIG. 20 is a cross-sectional view showing the second variation of the semiconductor device according to the first embodiment of the present disclosure.

FIG. 21 is a perspective view showing a third variation of the semiconductor device according to the first embodiment of the present disclosure.

FIG. 22 is a cross-sectional view showing the third variation of the semiconductor device according to the first embodiment of the present disclosure.

FIG. 23 is a perspective view showing a fourth variation of the semiconductor device according to the first embodiment of the present disclosure.

FIG. 24 is a cross-sectional view showing the fourth variation of the semiconductor device according to the first embodiment of the present disclosure.

FIG. 25 is a cross-sectional view showing a fifth variation of the semiconductor device according to the first embodiment of the present disclosure.

FIG. 26 is a side view showing a sixth variation of the semiconductor device according to the first embodiment of the present disclosure.

FIG. 27 is a plan view showing main parts of a semiconductor device according to a second embodiment of the present disclosure.

FIG. 28 is a cross-sectional view showing a semiconductor device according to a third embodiment of the present disclosure.

FIG. 29 is a perspective view showing a semiconductor device according to a fourth embodiment of the present disclosure.

FIG. 30 is a plan view showing the semiconductor device according to the fourth embodiment of the present disclosure.

FIG. 31 is a side view showing the semiconductor device according to the fourth embodiment of the present disclosure.

FIG. 32 is a cross-sectional view along line XXXII-XXXII in FIG. 30.

FIG. 33 is a perspective view showing a first variation of the semiconductor device according to the fourth embodiment of the present disclosure.

FIG. 34 is a plan view showing the first variation of the semiconductor device according to the fourth embodiment of the present disclosure.

FIG. 35 is a side view showing the first variation of the semiconductor device according to the fourth embodiment of the present disclosure.

FIG. 36 is a perspective view showing a second variation of the semiconductor device according to the fourth embodiment of the present disclosure.

FIG. 37 is a perspective view showing a third variation of the semiconductor device according to the fourth embodiment of the present disclosure.

FIG. 38 is a perspective view showing a fourth variation of the semiconductor device according to the fourth embodiment of the present disclosure.

FIG. 39 is a perspective view showing a fifth variation of the semiconductor device according to the fourth embodiment of the present disclosure.

FIG. 40 is a cross-sectional view showing a sixth variation of the semiconductor device according to the fourth embodiment of the present disclosure.

### DETAILED DESCRIPTION OF EMBODIMENTS

The following describes preferred embodiments of the present disclosure in detail with reference to the drawings.

The terms such as “first”, “second” and “third” in the present disclosure are used merely for identification, and are not intended to impose orders on the items to which these terms refer.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Furthermore, the phrase “an object A overlaps with an object B as viewed in a certain direction” includes, unless otherwise specified, “an object A overlaps with the entirety of an object B” and “an object A overlaps with a portion of an object B”. Furthermore, the phrase “a plane A faces (a first side or a second side) in a direction B” is not limited to the case where the angle of the plane A with respect to the direction B is 90°, but also includes the case where the plane A is inclined to the direction B.

### First Embodiment

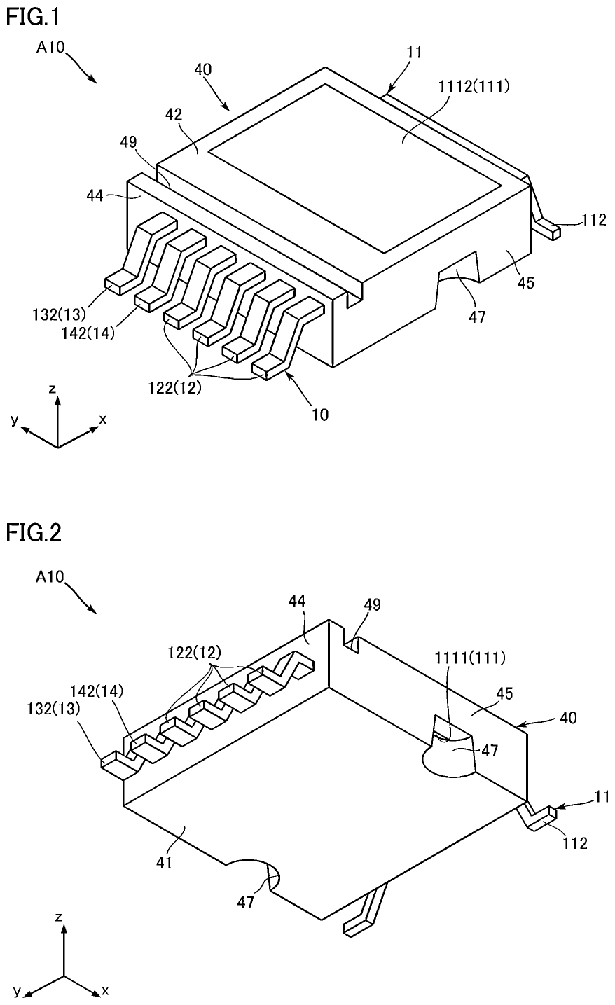

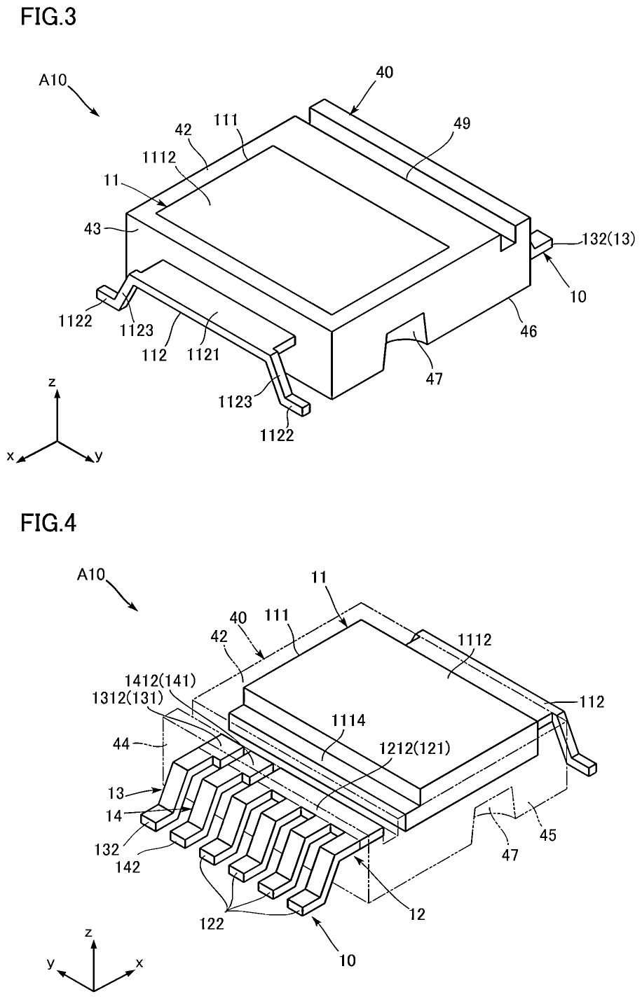

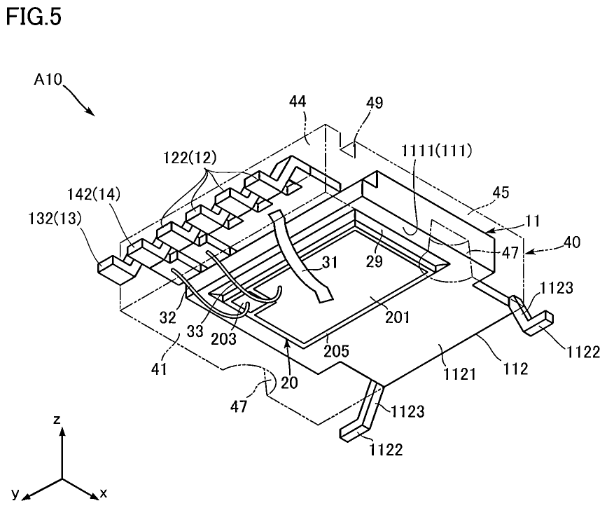

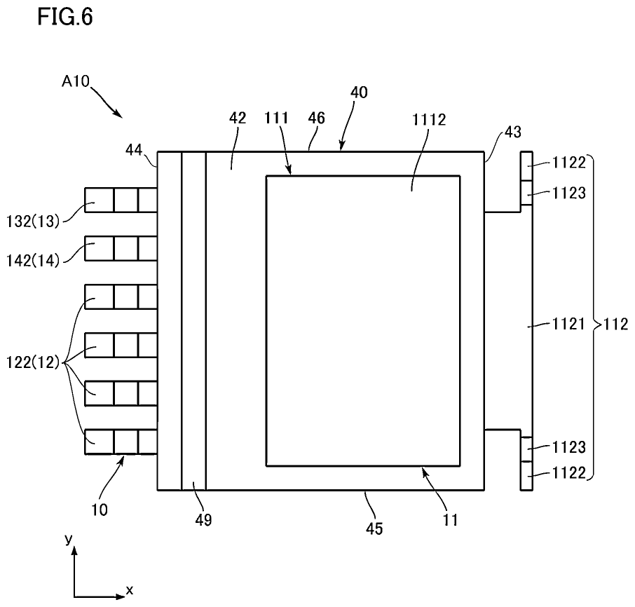

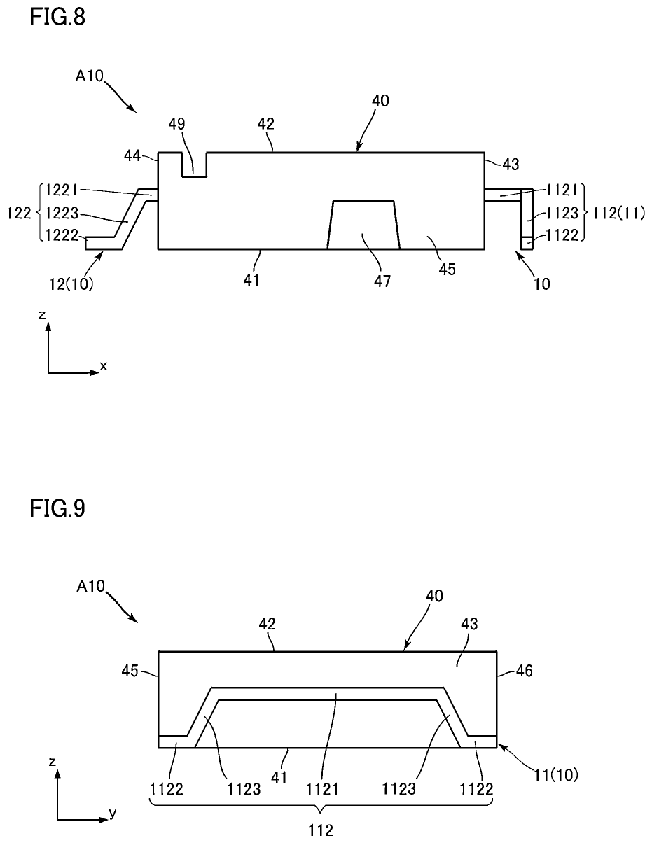

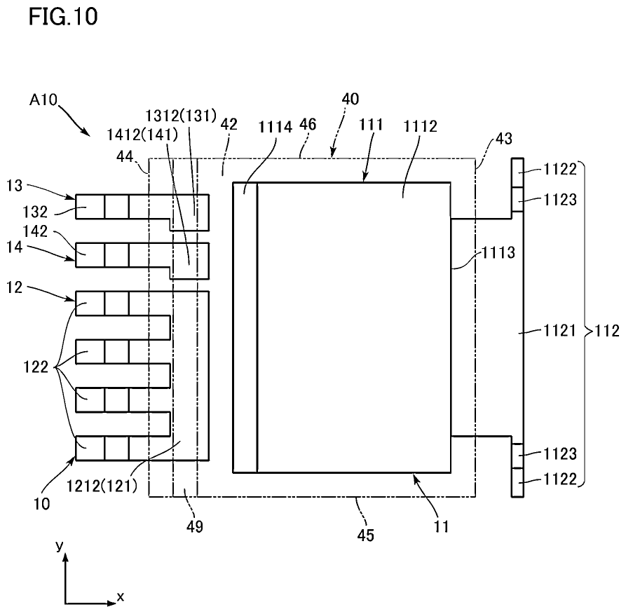

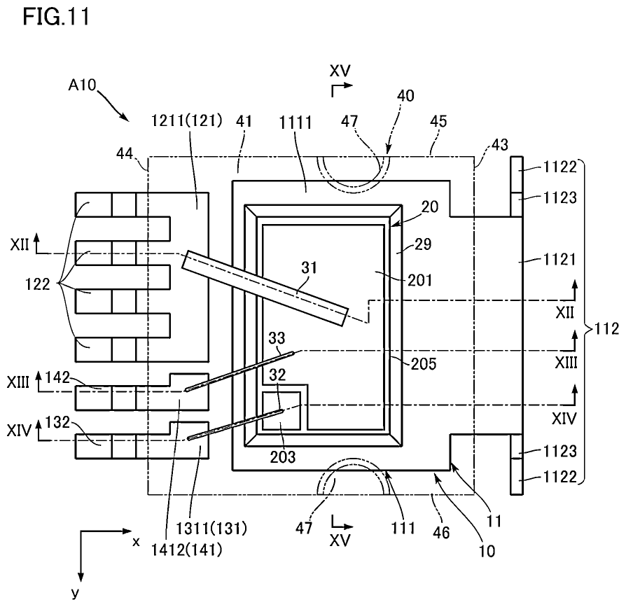

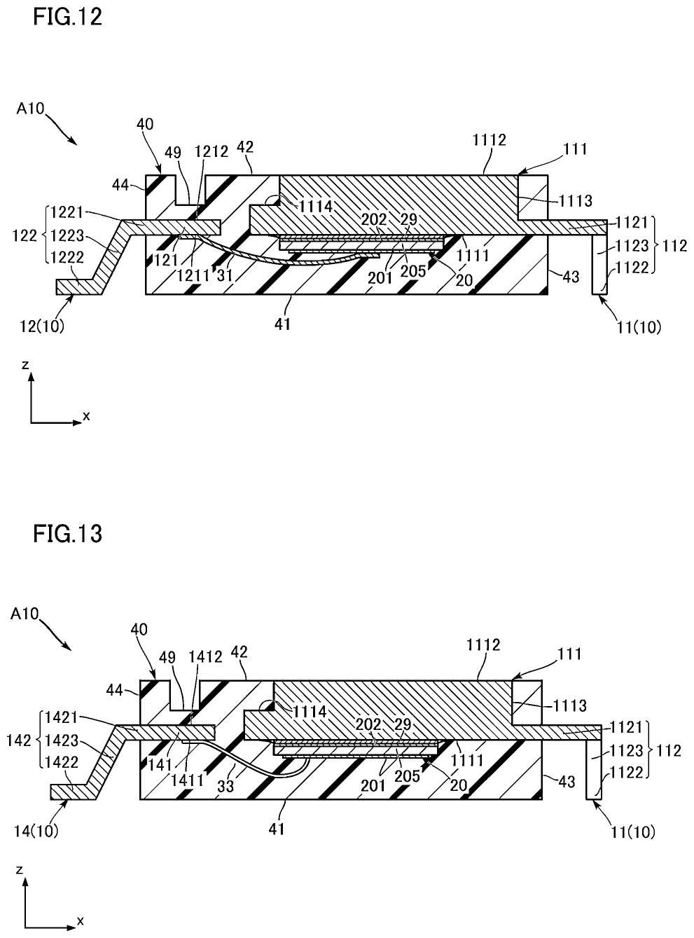

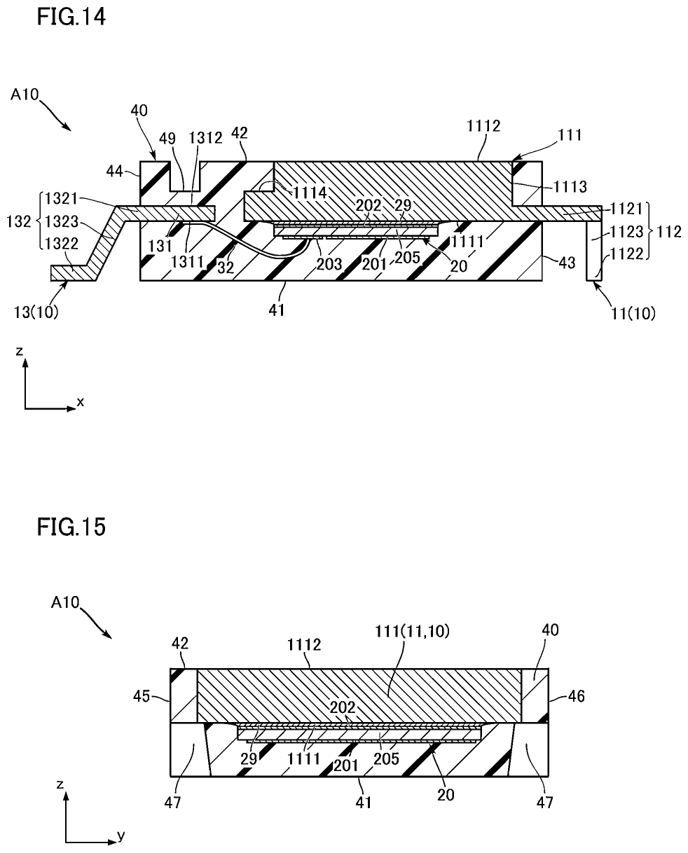

FIGS. 1 to 16 show a semiconductor device according to a first embodiment of the present disclosure. A semiconductor device A10 according to the present embodiment includes a conductive member 10, a semiconductor element 20, connecting members 31, 32, and 33, and a sealing resin 40. In these figures, a z direction is an example of a “thickness direction”, an x direction is an example of a “first direction”, and a y direction is an example of a “second direction”.

### Conductive Member 10:

The conductive member 10 constitutes a conduction path to the semiconductor element 20. The conductive member 10 of the present embodiment includes a first lead 11, a second lead 12, a third lead 13, and a fourth lead 14. The material of the first lead 11, the second lead 12, the third lead 13, and the fourth lead 14 is not particularly limited, and may contain copper (Cu) or a copper alloy. Appropriate portions of the first lead 11, the second lead 12, the third lead 13, and the fourth lead 14 may be plated with a metal such as silver (Ag), nickel (Ni), or tin (Sn).

### First Lead 11:

As shown in FIGS. 1 to 15, the first lead 11 has a die pad portion 111 and a first terminal portion 112. The die pad portion 111 has a first lead obverse surface 1111 and a first lead reverse surface 1112. The first lead obverse surface 1111 faces a first side in the z direction. The first lead reverse surface 1112 faces a second side in the z direction. The semiconductor element 20 is mounted on the first lead obverse surface 1111.

The die pad portion 111 of the present embodiment further has a first lead side surface 1113 and a first intermediate surface 1114. The first lead side surface 1113 is located between the first lead obverse surface 1111 and the first lead reverse surface 1112 in the z direction, and faces a first side in the x direction. The first intermediate surface 1114 is located between the first lead obverse surface 1111 and the first lead reverse surface 1112 in the z direction, and faces the second side in the z direction (the same side as the side that the first lead reverse surface 1112 faces).

The shape of the die pad portion 111 is not particularly limited. In the illustrated example, the die pad portion 111 has a rectangular shape as viewed in the z direction. The shape of each of the first lead obverse surface 1111 and the first lead reverse surface 1112 is not particularly limited, and in the illustrated example, is rectangular as viewed in the z direction.

The first terminal portion 112 has a first portion 1121, two second portions 1122, and two third portions 1123. The first portion 1121 is connected to the die pad portion 111, extends from the die pad portion 111 toward the first side in the x direction, and in the illustrated example, is parallel to an xy plane. In the present embodiment, the die pad portion 111 is larger than the first portion 1121 in the z direction. The first terminal portion 112 of the present embodiment has only one first portion 1121. The shape of the first portion 1121 is not particularly limited, and in the illustrated example, is rectangular as viewed in the z direction. The first portion 1121 is spaced apart from the first lead reverse surface 1112 in the z direction, and in the illustrated example, is in contact with the first lead obverse surface 1111. One surface of the first portion 1121 is flush with the first lead obverse surface 1111.

The two second portions 1122 are located on the first side in the z direction relative to the first portion 1121. The two second portions 1122 are used when the semiconductor device A10 is surface-mounted on a circuit board or the like.

The two third portions 1123 are located between the first portion 1121 and the two second portions 1122. The third portions 1123 extend from the first portion 1121 toward the first side in the z direction. In the illustrated example, the third portions 1123 are inclined to the z direction so as to extend outward in the y direction from the first portion 1121. The shape of each of the third portions 1123 is not particularly limited, and in the illustrated example, is rectangular as viewed in the z direction.

In the present embodiment, the two second portions 1122 extend outward in the y direction from the two third portions 1123. Furthermore, the two second portions 1122 are parallel to the y direction. The two second portions 1122 do not extend from the two third portions 1123 to the first side in the x direction. In the illustrated example, the two second portions 1122 and the two third portions 1123 are located at the same (or substantially the same) position in the x direction.

### Second Lead 12:

The second lead 12 is spaced apart from the first lead 11 (the die pad portion 111) to a second side in the x direction. The second lead 12 has a pad portion 121 and a plurality of second terminal portions 122.

The pad portion 121 has a second lead obverse surface 1211 and a second lead reverse surface 1212. The second lead obverse surface 1211 faces the first side in the z direction. The second lead reverse surface 1212 faces the second side in the z direction. The second lead obverse surface 1211 is connected to a connecting member 31. The shape of the pad portion 121 is not particularly limited. In the illustrated example, the pad portion 121 has a rectangular shape elongated in the y direction. As viewed in the z direction, the pad portion 121 is smaller than the die pad portion 111. Furthermore, the pad portion 121 is smaller than the die pad portion 111 in the z direction, and has the same size as the first portion 1121 in the z direction. In the illustrated example, the second lead obverse surface 1211 is located at the same (or substantially the same) position as the first lead obverse surface 1111 of the die pad portion 111 in the z direction.

The second terminal portions 122 are aligned in the y direction. Each of the second terminal portions 122 has a fourth portion 1221, a fifth portion 1222, and a sixth portion 1223.

The fourth portion 1221 is connected to the pad portion 121, extends from the pad portion 121 toward the second side in the x direction, and in the illustrated example, is parallel to the xy plane. The shape of the fourth portion 1221 is not particularly limited, and in the illustrated example, is rectangular as viewed in the z direction.

The fifth portion 1222 is located on the first side in the z direction relative to the fourth portion 1221. The fifth portion 1222 is used when the semiconductor device A10 is surface-mounted on a circuit board or the like. The fifth portion 1222 extends in the x direction.

The sixth portion 1223 is interposed between the fourth portion 1221 and the fifth portion 1222. The sixth portion 1223 extends from the fourth portion 1221 toward the first side in the z direction. In the illustrated example, the sixth portion 1223 is inclined to the z direction (yz plane). The shape of the sixth portion 1223 is not particularly limited, and in the illustrated example, is rectangular as viewed in the x direction.

### Third Lead 13:

The third lead 13 is spaced apart from the first lead 11 (die pad portion 111) toward the second side in the x direction. The third lead 13 is aligned with the second lead 12 in the y direction. The third lead 13 has a pad portion 131 and a third terminal portion 132.

The pad portion 131 has a third lead obverse surface 1311 and a third lead reverse surface 1312. The third lead obverse surface 1311 faces the first side in the z direction. The third lead reverse surface 1312 faces the second side in the z direction. The third lead obverse surface 1311 is connected to a connecting member 32. The shape of the pad portion 131 is not particularly limited, and in the illustrated example, is rectangular as viewed in the z direction. As viewed in the z direction, the pad portion 131 is smaller than the pad portion 121. Furthermore, the pad portion 131 is smaller than the die pad portion 111 in the z direction, and has the same size as the pad portion 121 in the z direction. In the illustrated example, the third lead obverse surface 1311 is located at the same (or substantially the same) position as the first lead obverse surface 1111 of the die pad portion 111 in the z direction.

The third terminal portion 132 has a seventh portion 1321, an eighth portion 1322, and a ninth portion 1323.

The seventh portion 1321 is connected to the pad portion 131, extends from the pad portion 131 toward the second side in the x direction, and in the illustrated example, is parallel to the xy plane. The shape of the seventh portion 1321 is not particularly limited, and in the illustrated example, is rectangular as viewed in the z direction.

The eighth portion 1322 is located on the first side in the z direction relative to the seventh portion 1321. The eighth portion 1322 is used when the semiconductor device A10 is surface-mounted on a circuit board or the like. The eighth portion 1322 extends in the x direction.

The ninth portion 1323 is interposed between the seventh portion 1321 and the eighth portion 1322. The ninth portion 1323 extends from the seventh portion 1321 toward the first side in the z direction. In the illustrated example, the ninth portion 1323 is inclined to the z direction (yz plane). The shape of the ninth portion 1323 is not particularly limited, and in the illustrated example, is rectangular as viewed in the x direction.

### Fourth Lead 14:

The fourth lead 14 is spaced apart from the first lead 11 (die pad portion 111) toward the second side in the x direction. The fourth lead 14 is located between the second lead 12 and the third lead 13 in the y direction. The fourth lead 14 has a pad portion 141 and a fourth terminal portion 142.

The pad portion 141 has a fourth lead obverse surface 1411 and a fourth lead reverse surface 1412. The fourth lead obverse surface 1411 faces the first side in the z direction. The fourth lead reverse surface 1412 faces the second side in the z direction. The fourth lead obverse surface 1411 is connected to a connecting member 33. The shape of the pad portion 141 is not particularly limited, and in the illustrated example, is rectangular as viewed in the z direction. As viewed in the z direction, the pad portion 141 is smaller than the pad portion 121 and has substantially the same size as the pad portion 131. Furthermore, the pad portion 141 is smaller than the die pad portion 111 in the z direction, and has the same size as each of the pad portion 121 and the pad portion 131 in the z direction. In the illustrated example, the fourth lead obverse surface 1411 is located at the same (or substantially the same) position as the first lead obverse surface 1111 of the die pad portion 111 in the z direction.

The fourth terminal portion 142 has a tenth portion 1421, an eleventh portion 1422, and a twelfth portion 1423.

The tenth portion 1421 is connected to the pad portion 141, extends from the pad portion 141 toward the second side in the x direction, and in the illustrated example, is parallel to the xy plane. The shape of the tenth portion 1421 is not particularly limited, and in the illustrated example, is rectangular as viewed in the z direction.

The eleventh portion 1422 is located on the first side in the z direction relative to the tenth portion 1421. The eleventh portion 1422 is used when the semiconductor device A10 is surface-mounted on a circuit board or the like. The eleventh portion 1422 extends in the x direction.

The twelfth portion 1423 is interposed between the tenth portion 1421 and the eleventh portion 1422. The twelfth portion 1423 extends from the tenth portion 1421 toward the first side in the z direction. In the illustrated example, the twelfth portion 1423 is inclined to the z direction (yz plane). The shape of the twelfth portion 1423 is not particularly limited, and in the illustrated example, is rectangular as viewed in the x direction.

### Semiconductor Element 20:

As shown in FIG. 5 and FIGS. 11 to 15, the semiconductor element 20 is mounted on the first lead obverse surface 1111 of the die pad portion 111. In the semiconductor device A10, the semiconductor element 20 is an n-channel metal-oxide-semiconductor field-effect transistor (MOSFET) having a vertical structure. The semiconductor element 20 is not limited to a MOSFET. The semiconductor element 20 may be another transistor such as an insulated gate bipolar transistor (IGBT). Furthermore, the semiconductor element 20 may be a diode. The semiconductor element 20 has a semiconductor layer 205, a first electrode 201, a second electrode 202, and a third electrode 203.

The semiconductor layer 205 includes a compound semiconductor substrate. The main material of the compound semiconductor substrate is silicon carbide (SiC). Alternatively, the main material of the compound semiconductor substrate may be silicon (Si).

The first electrode 201 is provided on a surface of the semiconductor layer 205 that faces the same side (first side) in the z direction as the side that the first lead obverse surface 1111 of the die pad portion 111 of the first lead 11 faces. The first electrode 201 corresponds to a source electrode of the semiconductor element 20.

The second electrode 202 is provided on a surface of the semiconductor layer 205 opposite to the first electrode 201 in the z direction. The second electrode 202 faces the first lead obverse surface 1111 of the die pad portion 111 of the first lead 11. The second electrode 202 corresponds to a drain electrode of the semiconductor element 20. In the present embodiment, the second electrode 202 is bonded to the first lead obverse surface 1111 via a bonding layer 29. The bonding layer 29 is solder, silver (Ag) paste, or calcined silver, for example.

The third electrode 203 is provided on the surface of the semiconductor layer 205 in the z direction where the first electrode 201 is provided, and is spaced apart from the first electrode 201. The third electrode 203 corresponds to a gate electrode of the semiconductor element 20. As viewed in the z direction, the area of the third electrode 203 is smaller than that of the first electrode 201.

### Connecting Members 31, 32, and 33:

The connecting member 31 is bonded to the first electrode 201 of the semiconductor element 20 and the second lead obverse surface 1211 of the pad portion 121 of the second lead 12. The material of the connecting member 31 is not particularly limited, and contains a metal such as aluminum (Al), copper (Cu), or gold (Au). The number of connecting members 31 is not particularly limited, and it is possible to provide a plurality of connecting members 31. In the illustrated example, the connecting member 31 is a flat band-like member containing aluminum (Al).

The connecting member 32 is connected to the third electrode 203 of the semiconductor element 20 and the third lead obverse surface 1311 of the pad portion 131 of the third lead 13. In the illustrated example, the connecting member 32 is a linear member narrower than the connecting member 31 and contains gold (Au).

The connecting member 33 is connected to the first electrode 201 of the semiconductor element 20 and the fourth lead obverse surface 1411 of the pad portion 141 of the fourth lead 14. In the illustrated example, the connecting member 33 is a linear member narrower than the connecting member 31 and contains gold (Au).

In the present embodiment, the first terminal portion 112 of the first lead 11 is a drain terminal, the second terminal portions 122 of the second lead 12 are source terminals, the third terminal portion 132 of the third lead 13 is a gate terminal, and the fourth terminal portion 142 of the fourth lead 14 is a source sense terminal.

### Sealing Resin 40:

As shown in FIGS. 1 to 15, the sealing resin 40 covers the semiconductor element 20, the connecting members 31, 32, and 33, and a part or the entirety of each of the first lead 11, the second lead 12, the third lead 13, and the fourth lead 14. The sealing resin 40 is electrically insulative. The sealing resin 40 is made of a material containing a black epoxy resin, for example. The sealing resin 40 has a first resin surface 41, a second resin surface 42, a third resin surface 43, a fourth resin surface 44, a fifth resin surface 45, and a sixth resin surface 46.

The first resin surface 41 faces the same side (the first side) in the z direction as the side that the first lead obverse surface 1111 of the die pad portion 111 of the first lead 11 faces. The second resin surface 42 faces the opposite side (the second side) from the first resin surface 41 in the z direction. The first lead reverse surface 1112 of the die pad portion 111 of the first lead 11 is exposed from the second resin surface 42. The second resin surface 42 and the first lead reverse surface 1112 are flush with each other. The first lead reverse surface 1112 is spaced apart from the third resin surface 43 in the x direction.

The third resin surface 43 faces the first side in the x direction. The first portion 1121 of the first terminal portion 112 of the first lead 11 passes through the third resin surface 43. In the present embodiment, only one first portion 1121 passes through the third resin surface 43. The first portion 1121 is spaced apart from the second resin surface 42 in the z direction.

The fourth resin surface 44 faces the opposite side (the second side) from the third resin surface 43 in the x direction. In the present embodiment, the fourth portions 1221 of the second terminal portions 122 of the second lead 12, the seventh portion 1321 of the third terminal portion 132 of the third lead 13, and the tenth portion 1421 of the fourth terminal portion 142 of the fourth lead 14 pass through the fourth resin surface 44.

The fifth resin surface 45 and the sixth resin surface 46 face away from each other in the y direction.

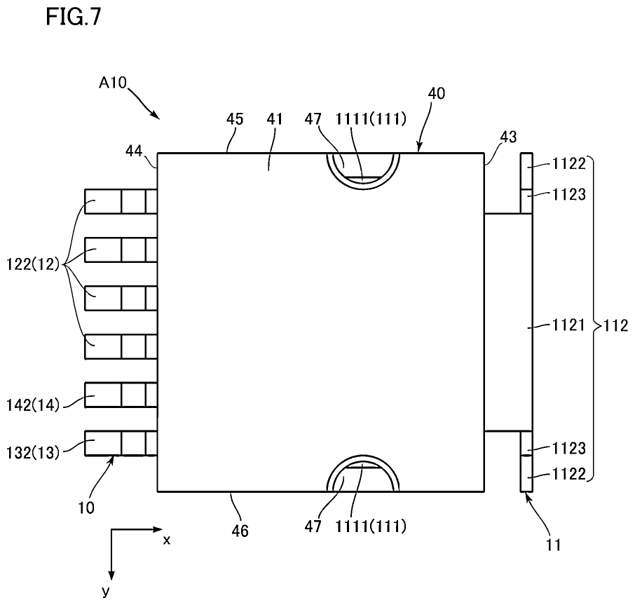

As shown in FIG. 7, the ends of the two second portions 1122 of the first terminal portions 112 of the first lead 11 in the y direction are substantially at the same positions as the fifth resin surface 45 and the sixth resin surface 46 of the sealing resin 40 in the y direction. The two second portions 1122 do not extend beyond the fifth resin surface 45 and the sixth resin surface 46 in the y direction.

In the illustrated example, the sealing resin 40 has a groove 49. The groove 49 is recessed from the second resin surface 42 in the z direction and extends in the y direction. The groove 49 reaches the fifth resin surface 45 and the sixth resin surface 46. The groove 49 is located between the first lead reverse surface 1112 and the fourth resin surface 44.

In the illustrated example, the sealing resin 40 has two recesses 47. One of the recesses 47 is recessed from the first resin surface 41 and the fifth resin surface 45. The other recess 47 is recessed from the first resin surface 41 and the sixth resin surface 46. The first lead obverse surface 1111 is partially exposed from the recesses 47.

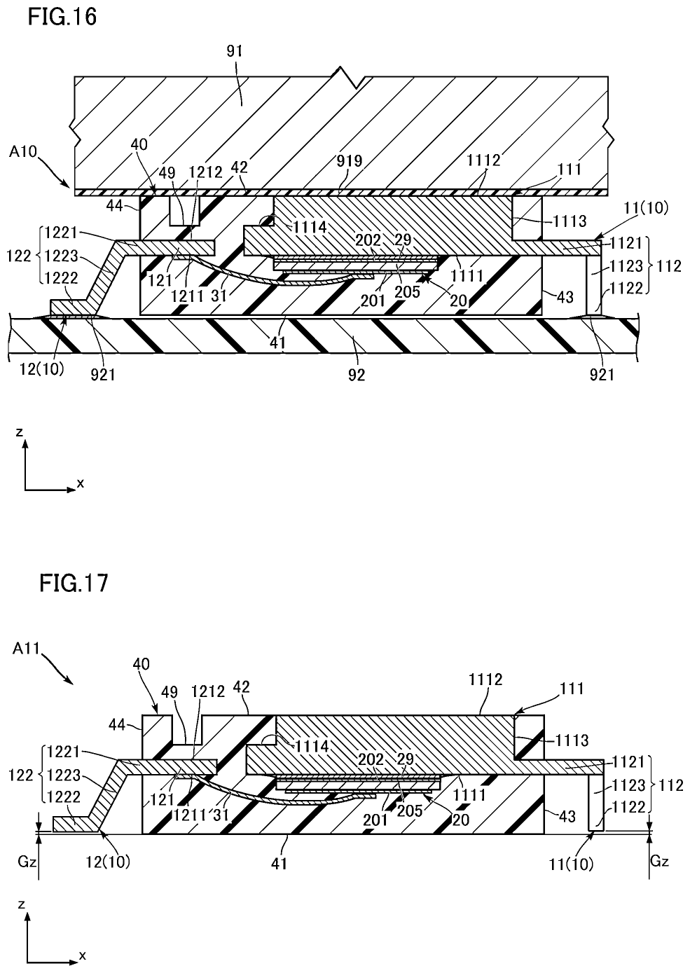

FIG. 16 shows a use state of the semiconductor device A10. In this use example, the semiconductor device A10 is surface-mounted on a circuit board 92. In other words, the second portions 1122 of the first terminal portion 112, the fifth portions 1222 of the second terminal portions 122, the eighth portion 1322 of the third terminal portion 132, and the eleventh portion 1422 of the fourth terminal portion 142 are electrically connected to a wiring pattern (not illustrated) of the circuit board 92 by, for example, solder 921. A heat sink 91 is arranged to face the first lead reverse surface 1112 of the die pad portion 111. In the illustrated example, a sheet member 919 is provided between the first lead reverse surface 1112 and the heat sink 91. The sheet member 919 is an insulating sheet, for example.

Next, advantages of the semiconductor device A10 will be described.

As shown in FIG. 16, the first lead reverse surface 1112 is exposed from the second resin surface 42. This makes it possible to arrange the heat sink 91 to face the first lead reverse surface 1112, for example. The second portions 1122 are located on the first side in the z direction relative to the first portion 1121. This makes it possible to surface-mount the semiconductor device A10 on the circuit board 92, for example, with use of the second portions 1122. The first lead reverse surface 1112 is spaced apart from the third resin surface 43 in the x direction. The first portion 1121 is spaced apart from the second resin surface 42 in the z direction. Thus, a portion of the sealing resin 40 exists between the first lead reverse surface 1112 and the first portion 1121. In this way, the first lead 11 can be more firmly held by the sealing resin 40.

The first terminal portion 112 has the third portions 1123. This makes it possible to more reliably support the second portions 1122.

The third portions 1123 extend also in the z direction. This makes it possible to reduce the dimension of the semiconductor device A10 in the x direction.

The first terminal portion 112 has the two second portions 1122. This improves the mounting strength of the semiconductor device A10.

The two second portions 1122 extend outward in the y direction from the third portions 1123. This further improves the mounting strength of the semiconductor device A10.

The size of the first portion 1121 in the y direction is smaller than that of the die pad portion 111 in the y direction. This allows the sealing resin 40 to hold the first lead 11 more firmly.

The second portions 1122 do not extend beyond the third portions 1123 in the x direction. This makes it possible to reduce the dimension of the semiconductor device A10 in the x direction.

The die pad portion 111 is larger than the first portion 1121 in the z direction. This makes it possible to transfer heat to a wider area in both the x direction and the y direction in the process of transferring heat from the semiconductor element 20 to the first lead reverse surface 1112. Thus, a wider area of the first portion 1121 can dissipate heat from the semiconductor element 20 to the heat sink 91 or the like, thereby enhancing heat dissipation efficiency.

One surface of the first portion 1121 is flush with the first lead obverse surface 1111. This makes it possible to increase the distance from the first portion 1121 to the second resin surface 42 in the z direction, thereby allowing the sealing resin 40 to hold the first lead 11 more firmly.

The sealing resin 40 is formed with the groove 49. This increases the distance along the surface of the sealing resin (hereinafter, “creepage distance”) from the first lead reverse surface 1112 to each of the second lead 12 (the fourth portions 1221), the third lead 13 (the seventh portion 1321), and the fourth lead 14 (the tenth portion 1421).

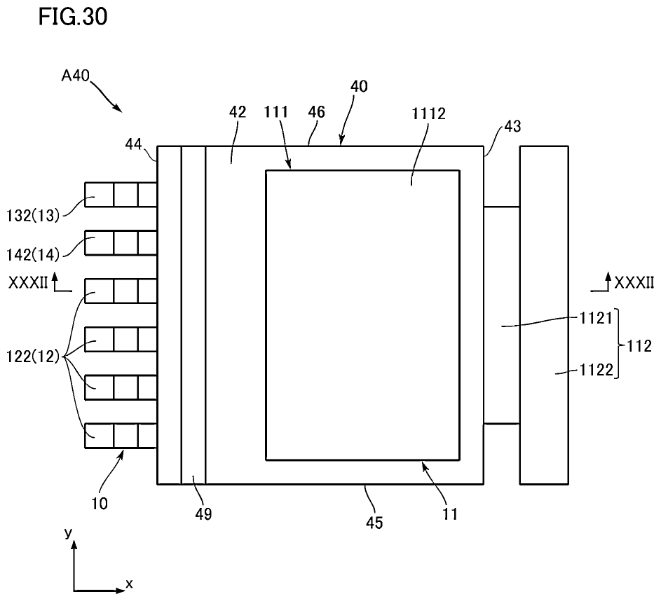

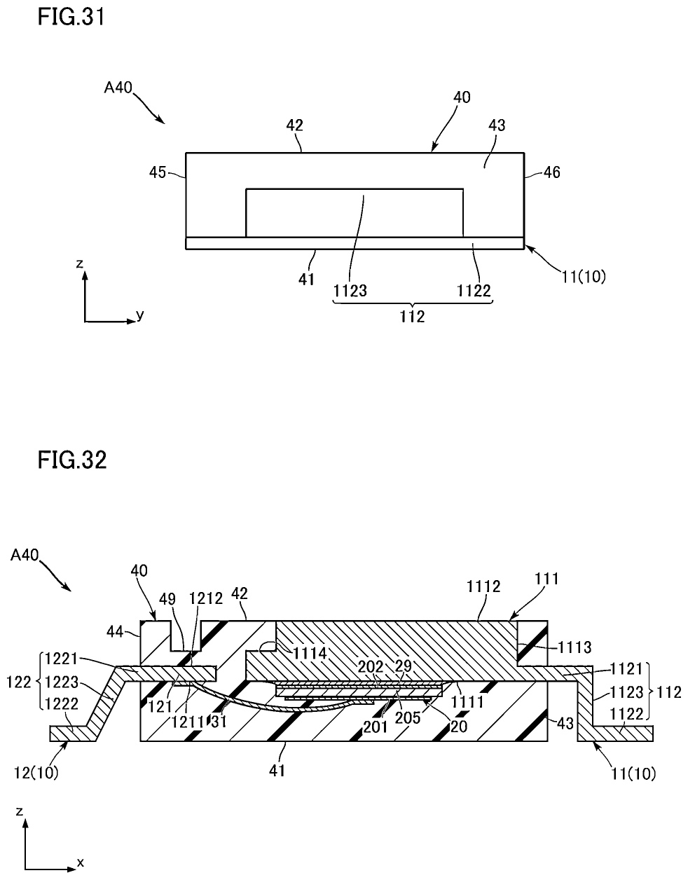

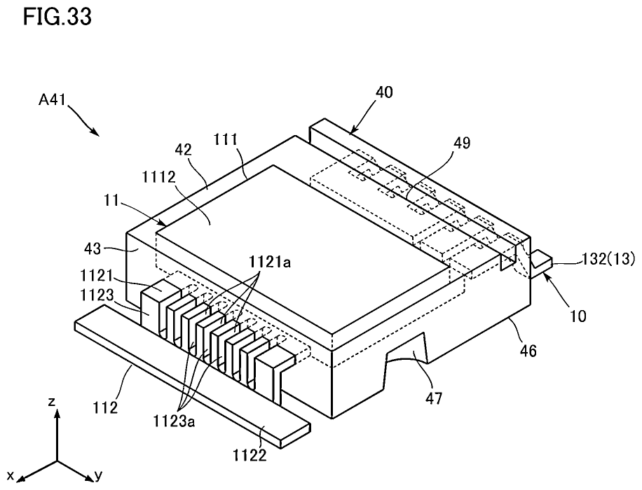

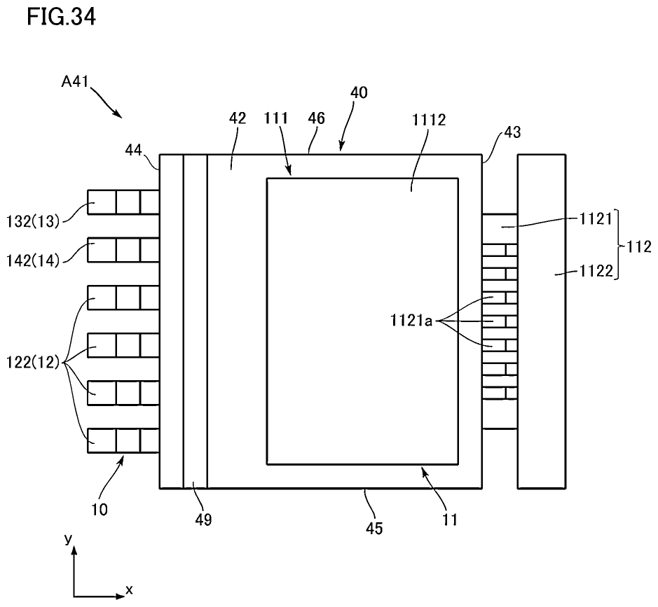

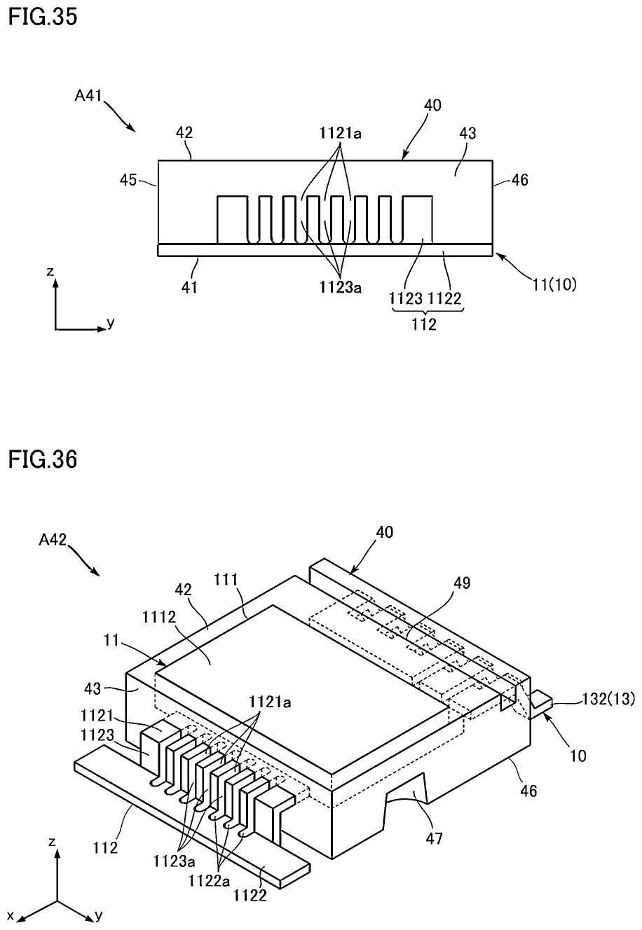

FIGS. 17 to 40 show other embodiments of the present disclosure. In these figures, elements that are the same as or similar to those in the above embodiment are provided with the same reference numerals as in the above embodiment. The configurations of the elements in each variation and each embodiment can be combined as appropriate as long as the combination does not cause technical contradictions.

### First Variation of the First Embodiment

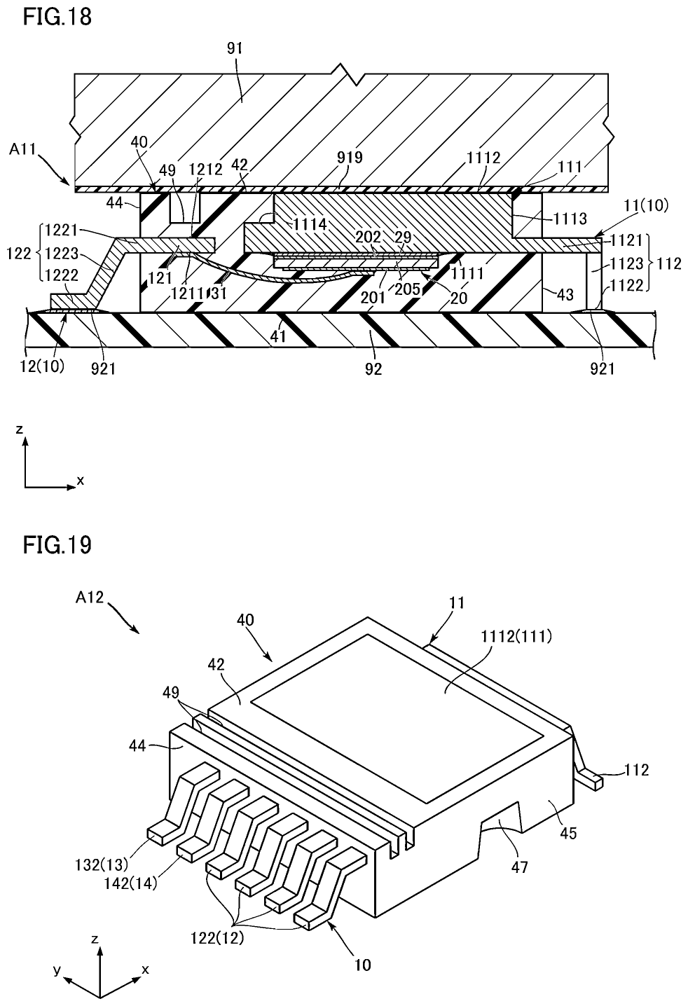

FIGS. 17 and 18 show a first variation of the semiconductor device A10. A semiconductor device A11 of the present variation is different from the above example in the relationship between the first resin surface 41 and each of the second portions 1122, the fifth portion 1222, the eighth portion 1322, and the eleventh portion 1422.

In the present variation, the second portions 1122, the fifth portion 1222, the eighth portion 1322, and the eleventh portion 1422 are located on the second side in the z direction (the side that the first lead reverse surface 1112 faces) relative to the first resin surface 41. The ends of the second portions 1122, the fifth portion 1222, the eighth portion 1322, and the eleventh portion 1422 on the first side in the z direction are spaced apart from the first resin surface 41 by a distance Gz.

According to the present variation, the semiconductor device A11 is surface-mountable and has the same advantages as the semiconductor device A10. The first resin surface 41 protrudes from the second portions 1122, the fifth portion 1222, the eighth portion 1322, and the eleventh portion 1422 toward the first side in the z direction by the distance Gz.

Accordingly, in a use state of the semiconductor device A11 shown in FIG. 18, pressing the heat sink 91 against the semiconductor device A11 can easily bring the first resin surface 41 in contact with the circuit board 92. This makes it possible to prevent the force applied by the heat sink 91 from acting on the first lead 11, the second lead 12, the third lead 13, the fourth lead 14, and the semiconductor element 20.

### Second Variation of the First Embodiment

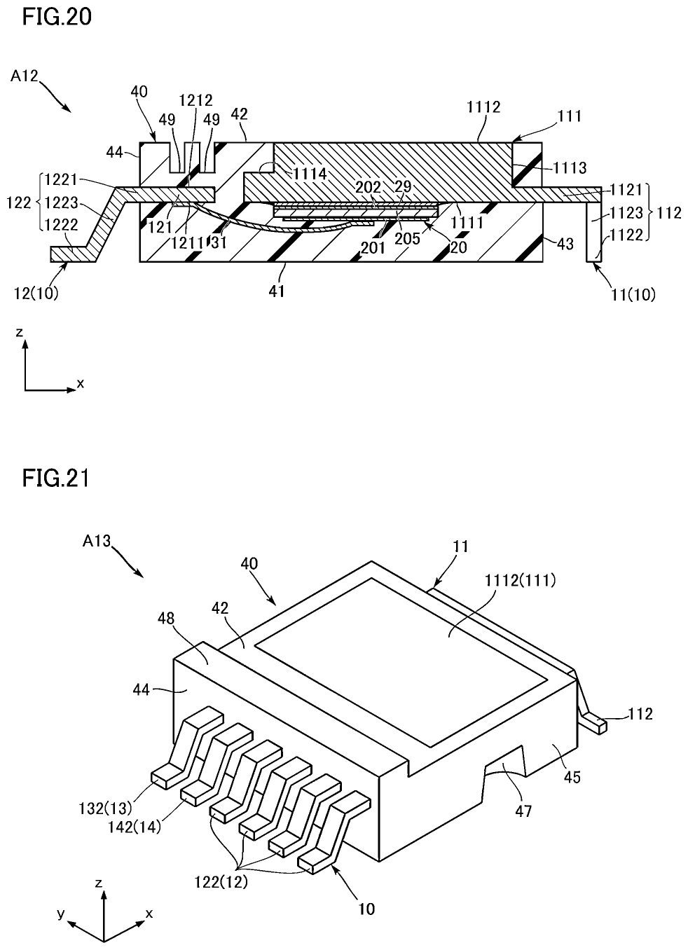

FIGS. 19 and 20 show a second variation of the semiconductor device A10. A semiconductor device A12 of the present variation has two grooves 49 provided in the sealing resin 40.

The grooves 49 extend in the y direction and reach the fifth resin surface 45 and the sixth resin surface 46. The two grooves 49 are spaced apart from each other in the x direction.

The present variation also allows surface-mounting of the semiconductor device A12 and achieves the same advantages as the above examples. The two grooves 49 can further increase the creepage distance between the first lead reverse surface 1112 and each of the second terminal portions 122, the third terminal portion 132, and the fourth terminal portion 142. As can be understood from the present variation, the number of grooves 49 is not particularly limited.

### Third Variation of the First Embodiment

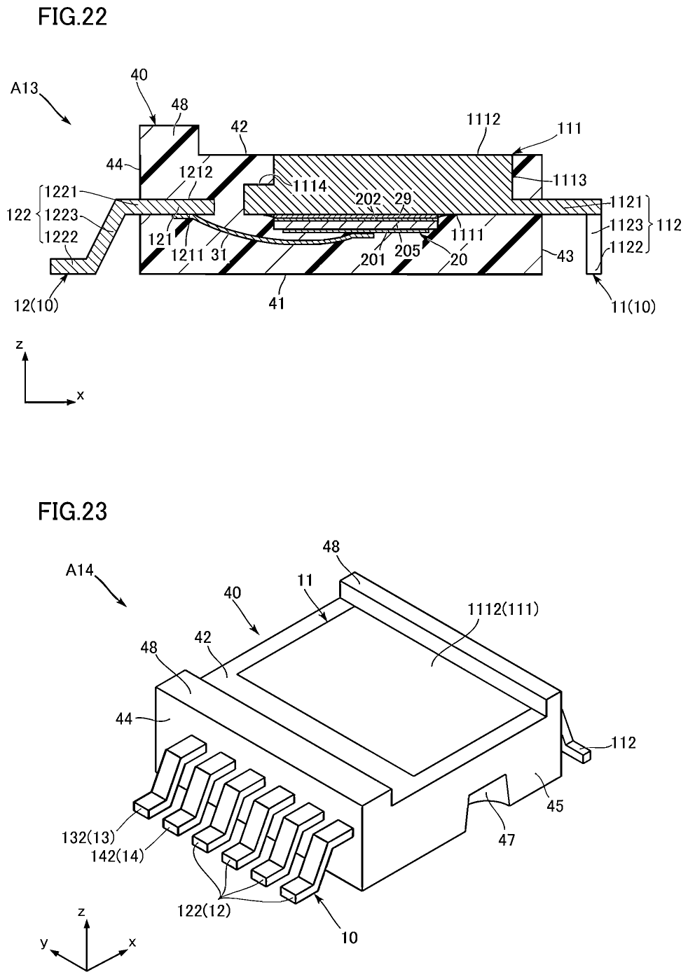

FIGS. 21 and 22 show a third variation of the semiconductor device A10. A semiconductor device A13 of the present variation has a protrusion 48 provided for the sealing resin 40.

The protrusion 48 protrudes from the second resin surface 42 to the second side in the z direction. The protrusion 48 extends in the y direction and reaches the fifth resin surface 45 and the sixth resin surface 46. In the illustrated example, the protrusion 48 is arranged at an end of the sealing resin 40 on the second side in the x direction, and is in contact with the fourth resin surface 44.

The present variation also allows surface-mounting of the semiconductor device A13. The protrusion 48 can increase the creepage distance between the first lead reverse surface 1112 and each of the second terminal portions 122, the third terminal portion 132, and the fourth terminal portion 142.

### Fourth Variation of the First Embodiment

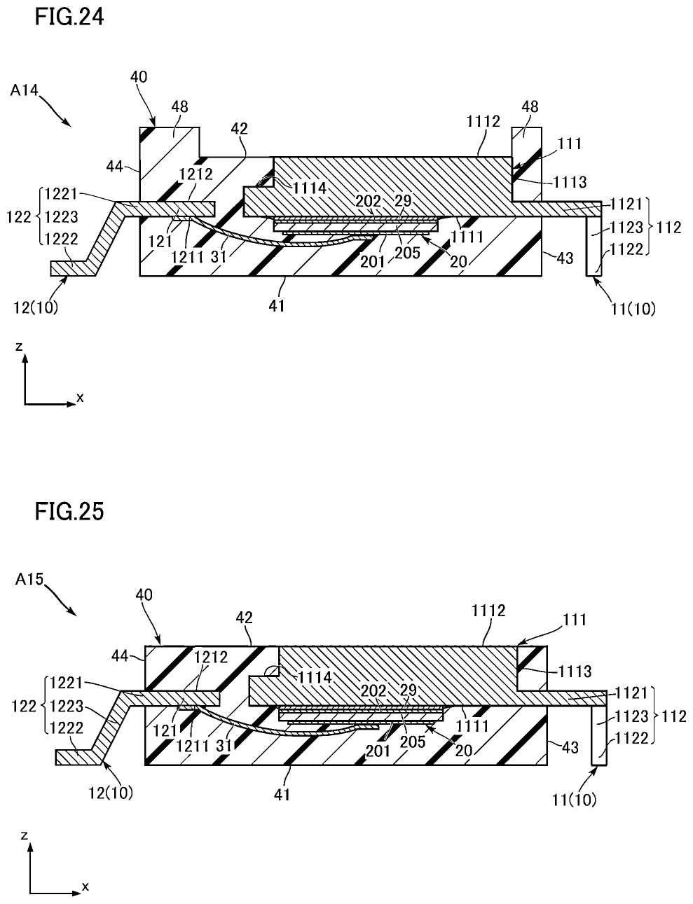

FIGS. 23 and 24 show a fourth variation of the semiconductor device A10. A semiconductor device A14 of the present variation has two protrusions 48 provided for the sealing resin 40.

The protrusions 48 protrude to the second side in the z direction. The protrusions 48 extend in the y direction and reach the fifth resin surface 45 and the sixth resin surface 46. The two protrusions 48 are spaced apart from each other with the first lead reverse surface 1112 therebetween in the x direction. One of the protrusions 48 is in contact with the fourth resin surface 44. The other protrusion 48 is in contact with the third resin surface 43.

The present variation also allows surface-mounting of the semiconductor device A14. The two protrusions 48 can further increase the creepage distance between the first lead reverse surface 1112 and each of the second terminal portions 122, the third terminal portion 132, and the fourth terminal portion 142. As can be understood from the present variation, the number of protrusions 48 is not particularly limited.

### Fifth Variation of the First Embodiment

FIG. 25 shows a fifth variation of the semiconductor device A10. In the semiconductor device A15 according to the present variation, the sealing resin 40 does not have any protrusions 48 or grooves 49. The present variation also allows surface-mounting of the semiconductor device A15. As can be understood from the present variation, the sealing resin 40 may be configured without any protrusions 48 or grooves 49.

### Sixth Variation of the First Embodiment

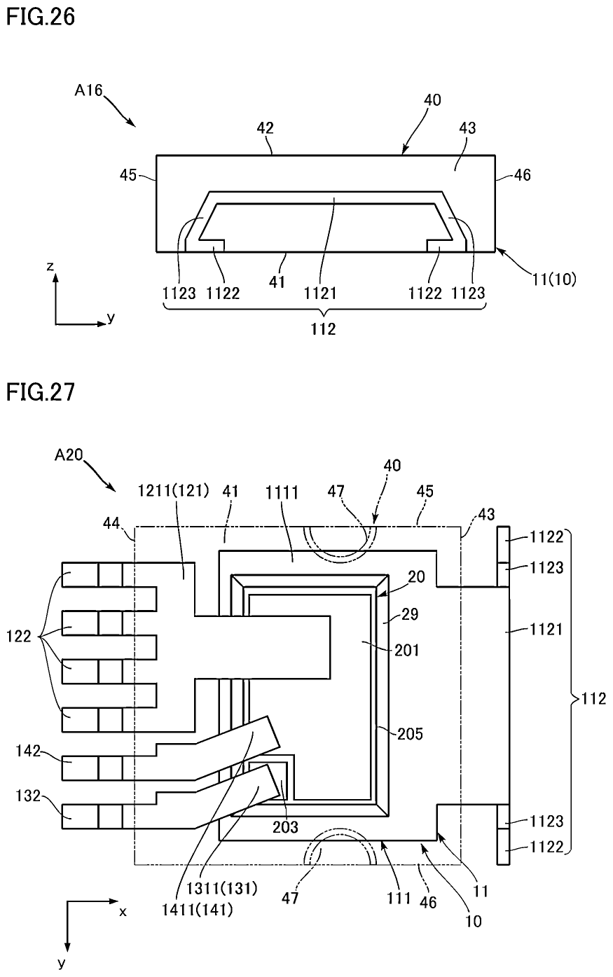

FIG. 26 shows a sixth variation of the semiconductor device A10. In a semiconductor device A16 according to the present variation, the two second portions 1122 extend inward in the x direction from the two respective third portions 1123. The present variation also allows surface-mounting of the semiconductor device A16. As can be understood from the present variation, the second portions 1122 are not limited to a particular shape, for example.

### Second Embodiment

FIG. 27 shows a semiconductor device according to a second embodiment of the present disclosure. A semiconductor device A20 according to the present embodiment does not include any of the connecting members 31, 32, and 33 described above.

In the present embodiment, the second lead reverse surface 1212 of the pad portion 121 of the second lead 12 is electrically connected to the first electrode 201 of the semiconductor element 20. The third lead reverse surface 1312 of the pad portion 131 of the third lead 13 is electrically connected to the third electrode 203 of the semiconductor element 20. The fourth lead reverse surface 1412 of the pad portion 141 of the fourth lead 14 is electrically connected to the first electrode 201 of the semiconductor element 20.

The present embodiment also allows surface-mounting of the semiconductor device A20. As can be understood from the present embodiment, the second lead 12, the third lead 13, and the fourth lead 14 may be electrically connected to the semiconductor element 20 in various manners.

### Third Embodiment

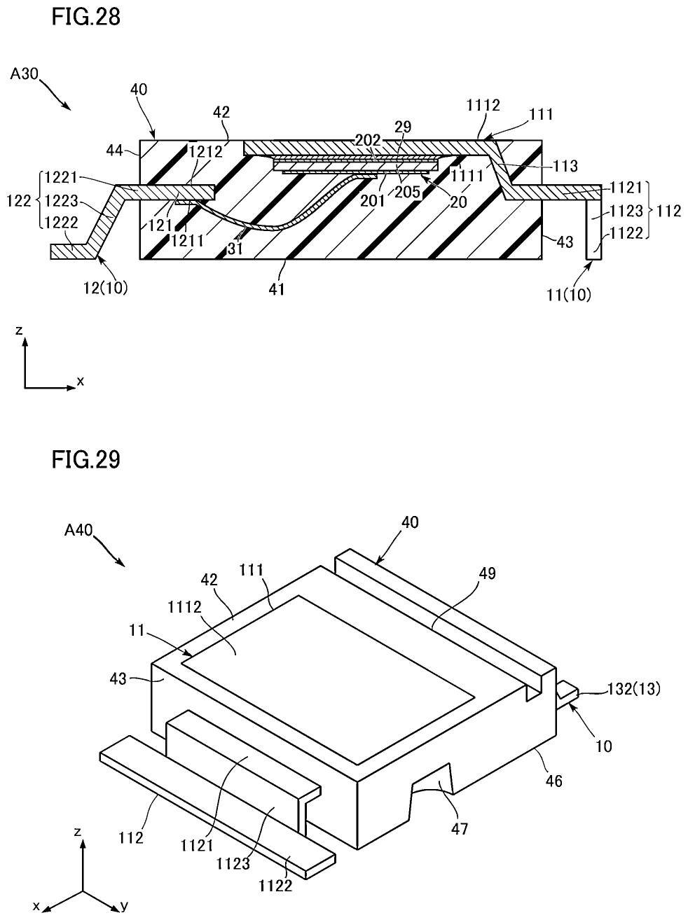

FIG. 28 shows a semiconductor device according to a third embodiment of the present disclosure. A semiconductor device A30 in the present embodiment is different from those in the above embodiments in the configuration of the first lead 11.

The first lead 11 of the present embodiment is configured such that the die pad portion 111 and the first portion 1121 have the same (or substantially the same) size in the z direction. The first lead 11 has a connecting portion 113. The connecting portion 113 connects the die pad portion 111 and the first portion 1121 of the first terminal portion 112 to each other. Even in the present embodiment, only one first portion 1121 passes through the third resin surface 43. In the present embodiment, the position of the first lead obverse surface 1111 in the z direction is different from the position of the surface of the first portion 1121 facing the first side in the z direction and the positions of the second lead obverse surface 1211, the third lead obverse surface 1311, and the fourth lead obverse surface 1411 in the z direction.

The present embodiment also allows surface-mounting of the semiconductor device A30. As can be understood from the present embodiment, the relationship between the size of the die pad portion 111 in the z direction and the size of the first portion 1121 in the z direction is not particularly limited.

### Fourth Embodiment

FIGS. 29 to 32 show a semiconductor device according to a fourth embodiment of the present disclosure. A semiconductor device A40 in the present embodiment is different from those in the above embodiments in the configuration of the first terminal portion 112.

According to the present embodiment, the first terminal portion 112 has a first portion 1121, a second portion 1122, and a third portion 1123. The third portion 1123 extends from the first portion 1121 toward the first side in the z direction, and has a rectangular shape as viewed in the x direction. The size of the third portion 1123 in the y direction is the same (or substantially the same) as the size of the first portion 1121 in the y direction.

The second portion 1122 extends from the third portion 1123 toward the first side (the outside) in the x direction. As viewed in the z direction, the second portion 1122 has a rectangular shape elongated in the y direction. The both ends of the second portion 1122 in the y direction protrude from the third portion 1123 to the outside in the y direction. The positions of the respective ends of the second portion 1122 in the y direction are substantially the same as the positions of the fifth resin surface 45 and the sixth resin surface 46 of the sealing resin 40, and do not extend outward from the fifth resin surface 45 and the sixth resin surface 46 in the y direction.

The present embodiment also allows surface-mounting of the semiconductor device A40. As can be understood from the present embodiment, the second portion 1122 and the third portion 1123 are not limited to a particular configuration.

### First Variation of the Fourth Embodiment

FIGS. 33 to 35 show a first variation of the semiconductor device A40. In a semiconductor device A41 of the present variation, the first portion 1121 of the first terminal portion 112 is formed with a plurality of through-holes 1121a, and the third portion 1123 is formed with a plurality of through-holes 1123a.

The through-holes 1121a pass through the first portion 1121 in the z direction. The shape of each through-hole 1121a is not particularly limited. In the illustrated example, each through-hole 1121a has a long hole shape elongated in the z direction. The through-holes 1121a are aligned in the y direction. Each of the through-holes 1121a is partially positioned within the sealing resin 40.

The through-holes 1123a pass through the third portion 1123 in the x direction. The shape of each through-hole 1123a is not particularly limited. In the illustrated example, each through-hole 1123a has a long hole shape elongated in the z direction. The through-holes 1123a are aligned in the y direction. A through-hole 1121a and a through-hole 1123a that are adjacent to each other are connected and in communication with each other.

The present variation also allows surface-mounting of the semiconductor device A41. Furthermore, providing the through-holes 1121a in the first portion 1121 and the through-holes 1123a in the third portion 1123 has an advantage of easily performing a bending process when forming the first terminal portion 112. Since a portion of each through-hole 1121a is positioned within the sealing resin 40, the alignment strength between the first terminal portion 112 and the sealing resin 40 can be enhanced.

### Second Variation of the Fourth Embodiment

FIG. 36 shows a second variation of the semiconductor device A40. In a semiconductor device A42 of the present variation, the first portion 1121 of the first terminal portion 112 is formed with a plurality of through-holes 1121a, the second portion 1122 is formed with a plurality of through-holes 1122a, and the third portion 1123 is formed with a plurality of through-holes 1123a. The through-holes 1121a and the through-holes 1123a are configured in the same manner as those of the semiconductor device A41.

The through-holes 1123a pass through the third portion 1123 in the z direction. The shape of each through-hole 1123a is not particularly limited. In the illustrated example, each through-hole 1123a has a long hole shape elongated in the z direction. The through-holes 1123a are aligned in the y direction. A through-hole 1122a and a through-hole 1123a that are adjacent to each other are connected and in communication with each other.

The present variation also allows surface-mounting of the semiconductor device A42. Furthermore, providing the through-holes 1121a in the first portion 1121, the through-holes 1123a in the third portion 1123, and the through-holes 1122a in the second portion 1122 has an advantage of easily performing a bending process when forming the first terminal portion 112.

### Third Variation of the Fourth Embodiment

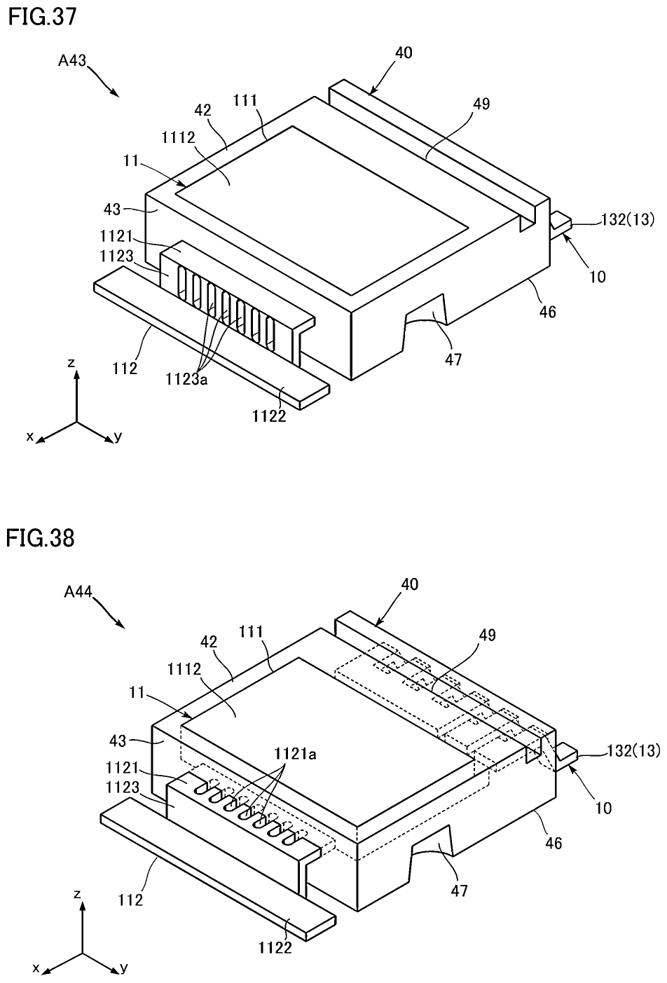

FIG. 37 shows a third variation of the semiconductor device A40. In a semiconductor device A43 of the present variation, the third portion 1123 of the first terminal portion 112 is formed with a plurality of through-holes 1123a. On the other hand, the first portion 1121 and the second portion 1122 are not formed with the above-described through-holes 1121a and the through-holes 1122a.

The present variation also allows surface-mounting of the semiconductor device A43. Furthermore, providing the through-holes 1123a in the third portion 1123 has an advantage of easily performing a bending process when forming the first terminal portion 112.

### Fourth Variation of the Fourth Embodiment

FIG. 38 shows a fourth variation of the semiconductor device A40. In a semiconductor device A44 of the present variation, the first portion 1121 of the first terminal portion 112 is formed with a plurality of through-holes 1121a. On the other hand, the second portion 1122 and the third portion 1123 are not formed with the above-described through-holes 1122a and the through-holes 1123a. The through-holes 1121a are spaced apart from the third portion 1123 in the x direction.

The present variation also allows surface-mounting of the semiconductor device A44. Since a portion of each through-hole 1121a is positioned within the sealing resin 40, the alignment strength between the first terminal portion 112 and the sealing resin 40 can be enhanced.

### Fifth Variation of the Fourth Embodiment

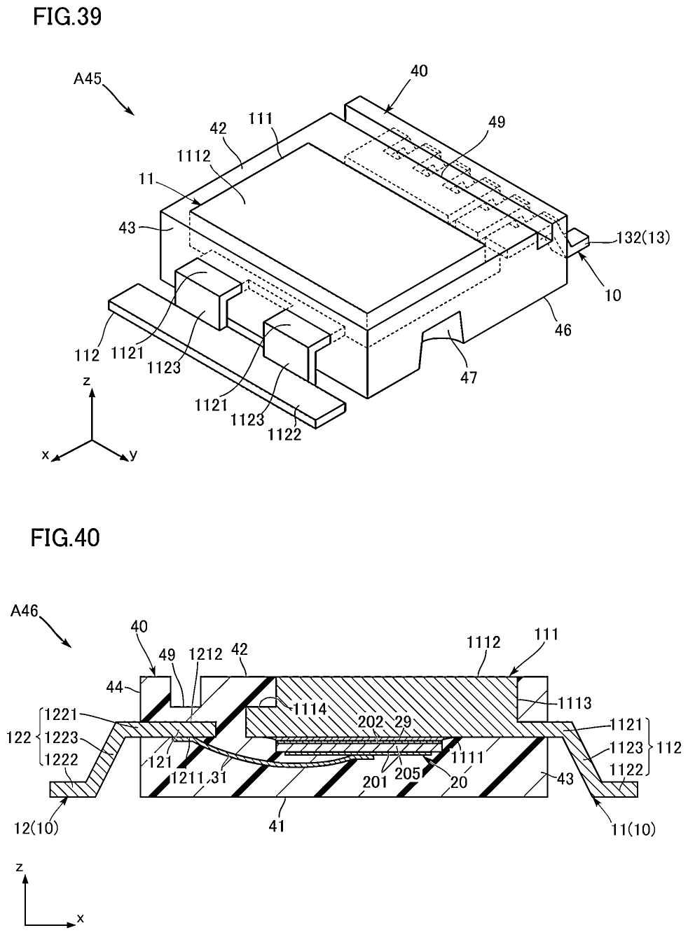

FIG. 39 shows a fifth variation of the semiconductor device A40. In the semiconductor device A45 according to the present variation, the first terminal portion 112 has two first portions 1121, two third portions 1123, and a second portion 1122.

The two first portions 1121 protrude from the third resin surface 43 of the sealing resin 40 toward the first side in the x direction. The two first portions 1121 are spaced apart from each other in the y direction. The two third portions 1123 are connected to the respective ends of the two first portions 1121 on the first side in the x direction. Each of the third portions 1123 has a shape along the z direction. The ends of the two third portions 1123 on the first side in the z direction are connected to the second portion 1122.

The present variation also allows surface-mounting of the semiconductor device A45. Since a portion of the sealing resin 40 is positioned between the two first portions 1121, the alignment strength between the first terminal portion 112 and the sealing resin 40 can be enhanced.

### Sixth Variation of the Fourth Embodiment

FIG. 40 shows a sixth variation of the semiconductor device A40. A semiconductor device A46 in the present variation is different from those in the above embodiments in the configuration of the first terminal portion 112. In the present variation, the third portion 1123 of the first terminal portion 112 is inclined to the z direction. The third portion 1123 is inclined to be further away from the first portion 1121 in the x direction as proceeding from the first portion 1121 to the second portion 1122 in the z direction.

The present variation also allows surface-mounting of the semiconductor device A46. As can be understood from the present variation, the specific configuration of the first terminal portion 112 can be changed in various manners.

The semiconductor device according to the present disclosure is not limited to the embodiments described above. Various design changes can be made to the specific configurations of the elements of the semiconductor device according to the present disclosure. The present disclosure includes the embodiments described in the following clauses.

Clause 1.

A semiconductor device comprising:
a semiconductor element;
a first lead including a die pad portion and a first terminal portion, the die pad portion including a first lead obverse surface that faces a first side in a thickness direction and on which the semiconductor element is mounted and a first lead reverse surface that faces a second side in the thickness direction; and
a sealing resin including a first resin surface facing the first side in the thickness direction, a second resin surface facing the second side in the thickness direction, and a third resin surface facing a first side in a first direction perpendicular to the thickness direction, the sealing resin covering the semiconductor element and a portion of the die pad portion,
wherein the first lead reverse surface is exposed from the second resin surface and spaced apart from the third resin surface in the first direction,
the first terminal portion includes a first portion and a second portion,
only one set of the first portion passes through the third resin surface, and the first portion is spaced apart from the second resin surface in the thickness direction, and
the second portion is located on the first side in the thickness direction relative to the first portion and used for mounting.

Clause 2.

The semiconductor device according to clause 1, wherein the first terminal portion includes a third portion interposed between the first portion and the second portion.

Clause 3.

The semiconductor device according to clause 2, wherein the third portion extends from the first portion toward the first side in the thickness direction.

Clause 4.

The semiconductor device according to clause 3, wherein the third portion is parallel to the thickness direction.

Clause 5.

The semiconductor device according to clause 3 or 4, wherein the first terminal portion includes two second portions, one of which is said second portion.

Clause 6.

The semiconductor device according to clause 5, wherein the two second portions extend outward from the third portion in a second direction perpendicular to the thickness direction and the first direction.

Clause 7.

The semiconductor device according to clause 6, wherein a size of the first portion in the second direction is smaller than a size of the die pad portion in the second direction.

Clause 8.

The semiconductor device according to clause 6 or 7, wherein the second portions do not extend beyond the third portion in the first direction.

Clause 9.

The semiconductor device according to clause 3 or 4, wherein the second portion extends from the third portion toward the first side in the first direction.

Clause 10.

The semiconductor device according to clause 9, wherein the second portion is along a plane perpendicular to the thickness direction.

Clause 11.

The semiconductor device according to clause 10, wherein a size of the second portion in a second direction perpendicular to the thickness direction and the first direction is larger than a size of the third portion in the second direction.

Clause 12.

The semiconductor device according to clause 11, wherein the second portion protrudes from the third portion to both sides in the second direction.

Clause 13.

The semiconductor device according to any of clauses 1 to 12, wherein the die pad portion is larger than the first portion of the first terminal portion in the thickness direction.

Clause 14.

The semiconductor device according to clause 13, wherein one side of the first portion is flush with the first lead obverse surface.

Clause 15.

The semiconductor device according to any of clauses 1 to 14, further comprising:
a connecting member connected to the semiconductor element; and
a second lead located on the second side in the first direction relative to the first lead, and including a pad portion that includes a second lead obverse surface facing the first side in the thickness direction,
wherein the connecting member is connected to the second lead obverse surface, and
the first lead obverse surface and the second lead obverse surface are located at a same position in the thickness direction.

Clause 16.

The semiconductor device according to clause 15,
wherein the sealing resin includes a fourth resin surface facing the second side in the first direction, and
the second lead includes a second terminal portion that includes a fourth portion passing through the fourth resin surface.

Clause 17.

The semiconductor device according to clause 16, wherein the second terminal portion includes a fifth portion located on the first side in the thickness direction relative to the fourth portion and used for mounting, and a sixth portion interposed between the fourth portion and the fifth portion.

REFERENCE NUMERALS

| | |
|---|---|
| A10, A11, A12, A13, A14, A15, | |
| A16, A20, A30, A40, A41, A42: | |
| Semiconductor device | |
| 10: Conductive member | 11: First lead |
| 12: Second lead | 13: Third lead |
| 14: Fourth lead | 20: Semiconductor element |
| 29: Bonding layer | 31: Connecting member |
| 32: Connecting member | 33: Connecting member |
| 40: Sealing resin | 41: First resin surface |
| 42: Second resin surface | 43: Third resin surface |
| 44: Fourth resin surface | 45: Fifth resin surface |
| 46: Sixth resin surface | 47: Recess |
| 48: Protrusion | 49: Groove |
| 91: Heat sink | 92: Circuit board |
| 111: Die pad portion | 112: First terminal portion |
| 113: Connecting portion | 121: Pad portion |
| 122: Second terminal portion | 131: Pad portion |
| 132: Third terminal portion | 141: Pad portion |
| 142: Fourth terminal portion | 201: First electrode |
| 202: Second electrode | 203: Third electrode |
| 205: Semiconductor layer | 919: Sheet member |
| 921: Solder | 1111: First lead obverse surface |
| 1112: First lead reverse surface | 1113: First lead side surface |
| 1114: First intermediate surface | 1121: First portion |
| 1122: Second portion | 1121a, 1122a, 1123: Third portion |
| 1123a: Through-hole | 1211: Second lead obverse surface |
| 1212: Second lead reverse surface | 1221: Fourth portion |
| 1222: Fifth portion | 1223: Sixth portion |
| 1311: Third lead obverse surface | 1312: Third lead reverse surface |
| 1321: Seventh portion | 1322: Eighth portion |
| 1323: Ninth portion | 1411: Fourth lead obverse surface |
| 1412: Fourth lead reverse surface | 1421: Tenth portion |
| 1422: Eleventh portion | 1423: Twelfth portion |
| Gz: Distance | |

1. A semiconductor device comprising:
a semiconductor element;
a first lead including a die pad portion and a first terminal portion, the die pad portion including a first lead obverse surface that faces a first side in a thickness direction and on which the semiconductor element is mounted and a first lead reverse surface that faces a second side in the thickness direction; and
a sealing resin including a first resin surface facing the first side in the thickness direction, a second resin surface facing the second side in the thickness direction, and a third resin surface facing a first side in a first direction perpendicular to the thickness direction, the sealing resin covering the semiconductor element and a portion of the die pad portion,
wherein the first lead reverse surface is exposed from the second resin surface and spaced apart from the third resin surface in the first direction,
the first terminal portion includes a first portion and a second portion,
only one set of the first portion passes through the third resin surface, and the first portion is spaced apart from the second resin surface in the thickness direction, and
the second portion is located on the first side in the thickness direction relative to the first portion and used for mounting.

2. The semiconductor device according to claim 1, wherein the first terminal portion includes a third portion interposed between the first portion and the second portion.

3. The semiconductor device according to claim 2, wherein the third portion extends from the first portion toward the first side in the thickness direction.

4. The semiconductor device according to claim 3, wherein the third portion is parallel to the thickness direction.

5. The semiconductor device according to claim 3, wherein the first terminal portion includes two second portions, one of which is said second portion.

6. The semiconductor device according to claim 5, wherein the two second portions extend outward from the third portion in a second direction perpendicular to the thickness direction and the first direction.

7. The semiconductor device according to claim 6, wherein a size of the first portion in the second direction is smaller than a size of the die pad portion in the second direction.

8. The semiconductor device according to claim 6, wherein the second portions do not extend beyond the third portion in the first direction.

9. The semiconductor device according to claim 3, wherein the second portion extends from the third portion toward the first side in the first direction.

10. The semiconductor device according to claim 9, wherein the second portion is along a plane perpendicular to the thickness direction.

11. The semiconductor device according to claim 10, wherein a size of the second portion in a second direction perpendicular to the thickness direction and the first direction is larger than a size of the third portion in the second direction.

12. The semiconductor device according to claim 11, wherein the second portion protrudes from the third portion to both sides in the second direction.

13. The semiconductor device according to claim 1, wherein the die pad portion is larger than the first portion of the first terminal portion in the thickness direction.

14. The semiconductor device according to claim 13, wherein one side of the first portion is flush with the first lead obverse surface.

15. The semiconductor device according to claim 1, further comprising:
a connecting member connected to the semiconductor element; and
a second lead located on the second side in the first direction relative to the first lead, and including a pad portion that includes a second lead obverse surface facing the first side in the thickness direction,
wherein the connecting member is connected to the second lead obverse surface, and
the first lead obverse surface and the second lead obverse surface are located at a same position in the thickness direction.

16. The semiconductor device according to claim 15,
wherein the sealing resin includes a fourth resin surface facing the second side in the first direction, and
the second lead includes a second terminal portion that includes a fourth portion passing through the fourth resin surface.

17. The semiconductor device according to claim 16, wherein the second terminal portion includes a fifth portion located on the first side in the thickness direction relative to the fourth portion and used for mounting, and a sixth portion interposed between the fourth portion and the fifth portion.
